(19) United States
(12) Patent Application Publication
(10) Pub. No.: US 2026/0231729 A1
(43) Pub. Date: Aug. 6, 2026

(54) SEMICONDUCTOR PROCESSING CHAMBER COMPONENT WITH A METAL BODY AND LASER GLAZED CERAMIC COATING

(71) Applicant: Lam Research Corporation, Fremont, CA (US)

(72) Inventors: Eric A. PAPE, Santa Cruz, CA (US); David Joseph WETZEL, Santa Clara, CA (US); Lin XU, Fremont, CA (US); Jesu Titus IRUDAYARAJ, Bangalore (IN)

(21) Appl. No.: 19/155,019

(22) PCT Filed: Jan. 22, 2024
(86) PCT No.: PCT/US2024/012423

§ 371 Date: Aug. 8, 2025

Related U.S. Application Data
(60) Provisional application No. 63/447,298, filed on Feb. 21, 2023.

(51) Int. Cl. H10P 72/72; C23C 4/11; C23C 4/134; C25D 11/04; H01J 37/32

(52) U.S. Cl. CPC H10P 72/722; C23C 4/11; C23C 4/134; C25D 11/04; H01J 37/32715

(57) ABSTRACT

A component for use in a semiconductor processing chamber is provided. A metal component body is provided with a ceramic coating on a surface of the metal component body, wherein the ceramic coating has a thickness in a range of 40 pm to 600 pm, and wherein a surface of the ceramic coating is a laser glazed ceramic coating.

### CROSS-REFERENCE TO RELATED APPLICATION

This application claims the benefit of priority of U.S. Application No. 63/447,298, filed Feb. 21, 2023, which is incorporated herein by reference for all purposes.

### BACKGROUND

The disclosure relates to a plasma processing chamber for forming semiconductor devices on a semiconductor wafer.

In the formation of semiconductor devices, plasma processing chambers are used to process the semiconductor devices. The plasma processing chamber may use an electrostatic chuck (ESC). The ESC may comprise a metal baseplate bonded to a ceramic plate. The ESC may be subjected to a corrosive plasma environment.

### SUMMARY

To achieve the foregoing and in accordance with the purpose of the present disclosure, a component for use in a semiconductor processing chamber is provided. A metal component body is provided with a ceramic coating on a surface of the metal component body, wherein the ceramic coating has a thickness in a range of 40 μm to 600 μm, and wherein a surface of the ceramic coating is a laser glazed ceramic coating.

In another manifestation, a method for forming a component for use in a semiconductor processing chamber is provided. A metal component body is provided. A ceramic coating is plasma sprayed over a surface of the metal component body. A surface of the ceramic coating is laser glazed.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a flow chart of a process used in some embodiments.

FIGS. 2A-D are cross-sectional views of a component provided in some embodiments.

FIG. 3 is a schematic view of a plasma processing chamber that may employ some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth to provide a thorough understanding of the present disclosure. It will be apparent, however, to one skilled in the art, that the present disclosure may be practiced without some or all these specific details. In other instances, well known process steps and/or structures have not been described in detail to not unnecessarily obscure the present disclosure.

Within etch or deposition semiconductor processing chambers, wafers are generally held in place via an electrostatic chuck (ESC), such as a pedestal system. The ESC may comprise an electrically conductive baseplate, a ceramic plate, and a bond layer bonding the baseplate to the ceramic plate.

The metal parts of an ESC can be subjected to large voltages as compared to the chamber body. In addition, the metal parts of the ESC may be subjected to chemical and plasma degradation. There is a need to protect the metal parts of ESCs from chemical and plasma degradation and electrical discharge.

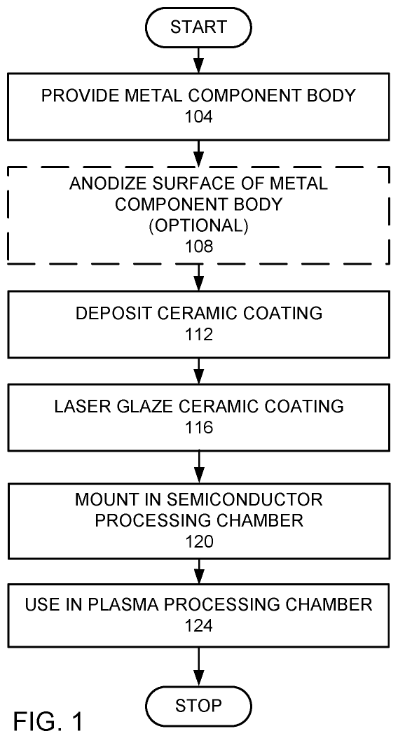

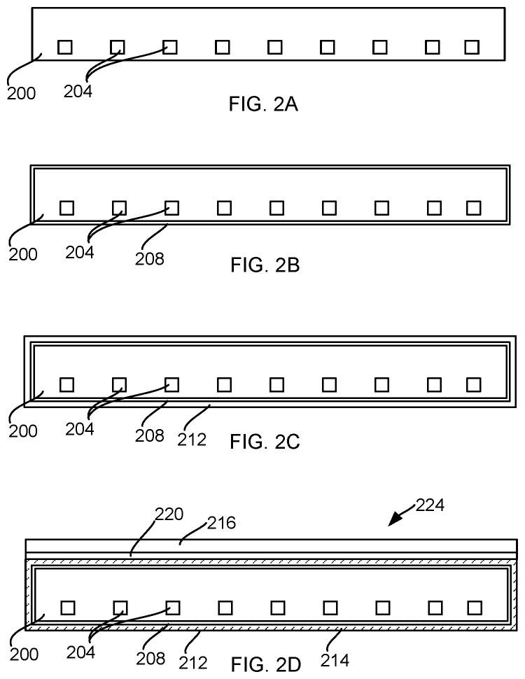

FIG. 1 is a flow chart of methods that may be used in some embodiments. A metal component body is provided (step 104). In some embodiments, the metal component body is a baseplate of an ESC. FIG. 2A is a schematic cross-sectional view of a component body 200 that is a baseplate of an ESC according to some embodiments. In some embodiments, the component body 200 is aluminum. In some embodiments the aluminum component body 200 is made of an aluminum alloy, such as aluminum 6061. In some embodiments, the component body 200 has temperature control channels 204 for providing a flow of a temperature control fluid.

In some embodiments, an optional surface anodization of the surface of the component body is provided (step 108). In some embodiments, a Type I anodization of aluminum 6061 is used to provide an anodized layer with a thickness in the range of 5 μm to 15 μm. The Type I anodization process is a process where an aluminum component body is subjected to a chromic acid bath to provide a thin anodic layer. In some embodiments, a Type III anodization process is used to anodize the surface of the component body. The Type III anodization process (also referred to as hard anodization or hard-coat anodization) is a process where an aluminum component body is subjected to a sulfuric bath at a temperature of 0° C. to 3° C. and high voltage (up to 100V) to create the oxide or “anodized” layer. In some embodiments, the Type III anodized layer has a thickness in the range of 25 μm to 125 μm. In other embodiments, a Type II anodization process is used to anodize the surface of the component body. The Type II anodization process is where the surface of the component body is placed in a sulfuric bath at about 20° C. to 25° C. 68-72 to form an aluminum oxide anodized layer on the surface as well as a depth into the aluminum material. In some embodiments, the Type II anodized layer has a thickness in the range of 1.5 μm to 30 μm. In some embodiments, the anodization layer is sealed. In some embodiments, the anodization layer is not sealed. In some embodiments, the surface of the component body is not anodized. In some embodiments, a native oxide coating is on the surface of the component body.

£ FIG. 2B is a schematic cross-sectional view of the component body 200 after an anodization layer 208 has been formed. The drawing is not to scale in order to better illustrate the anodization layer 208. In some embodiments, a native oxide layer is in place of the anodization layer 208. In some embodiments, there is no anodization layer 208.

Next, a ceramic coating is deposited over the surface of the component body 200 (step 112). In some embodiments, the ceramic coating is deposited by a plasma spray process, such as an atmospheric plasma spray (APS). Atmospheric plasma spraying is a type of thermal spraying in which a torch is formed by applying an electrical potential between two electrodes, leading to the ionization of an accelerated gas (plasma). Torches of this type can readily reach temperatures of thousands of degrees Celsius, liquefying high melting point materials such as ceramics. Ceramic particles are injected into the jet, melted, and then accelerated towards the component body 200 so that the molten or plasticized material coats the surface of the component and cools, forming a solid, conformal coating. In some embodiments, the thermal spraying provides a layer with a thickness in the range of 10 μm to more than 1000 μm. In some embodiments, the ceramic coating comprises a metal oxide. In some embodiments, the ceramic coating comprises at least one of aluminum oxide (also called alumina), yttrium oxide (also called yttria), magnesium aluminum oxide (MgAl₂O₄) (spinel), and yttrium aluminum oxide. In some embodiments, the ceramic coating has a thickness in the range of 100 μm and 600 μm.

FIG. 2C is a schematic cross-sectional view of the component body 200 after a ceramic coating 212 has been deposited (step 112). The drawing is not to scale in order to better illustrate the ceramic coating 212.

Next, the ceramic coating 212 is laser glazed (step 116). Laser glazing is a process of melting the surface of the ceramic coating 212 using a laser to form a layer of melted material that resolidifies, and that may crystallize, into a laser glazed surface of the ceramic coating 212. In some embodiments, the laser glazing laser glazes at least 70% of the thickness of the ceramic coating 212 by melting the surface of the ceramic coating 212 where the melted surface solidifies, and may crystallize, to provide a surface with a glassy appearance. In some embodiments, the laser is a continuous high-energy laser beam that is scanned across the surface of the ceramic coating 212. In some embodiments, the laser beam is provided by a continuous wave carbon dioxide (CO₂) laser with power in the range of 100 watts (W) to 1,000 W. In some embodiments, the laser beam is provided by a continuous wave CO₂ laser with power in the range of 100 W to 600 W. In some embodiments, the laser beam is provided by a continuous wave CO₂ laser with power in the range of 600 W to 1000 W. In some embodiments, a scanning rate is in the range of 5 millimeters per second (mm/s) to 40 mm/s. The laser power and scanning speed combination allow for the melting of the ceramic coating 212 with limited surface evaporation and sputtering and limited creation of defects or surface craters. In some embodiments the laser beam has a full width at half maximum (FWHM) in the range of 1-10 mm. In some embodiments, the laser beam has a FWHM in the range of 3-6 mm.

Next, the component body 200 is mounted in a semiconductor processing chamber (step 120). In some embodiments, the component body 200 is assembled with other parts to form the ESC. In some embodiments, a ceramic plate is bonded to the component body 200 by a bonding layer to form the ESC. FIG. 2D is a schematic cross-sectional view of the component body 200 with a ceramic coating 212 with a laser glazed ceramic coating 214, indicated by the shading, where the component body 200—is bonded to a ceramic plate 216 by a bond layer 220 to form an ESC 224 that may be provided in some embodiments. In some embodiments, the ceramic plate 216 comprises ceramic alumina.

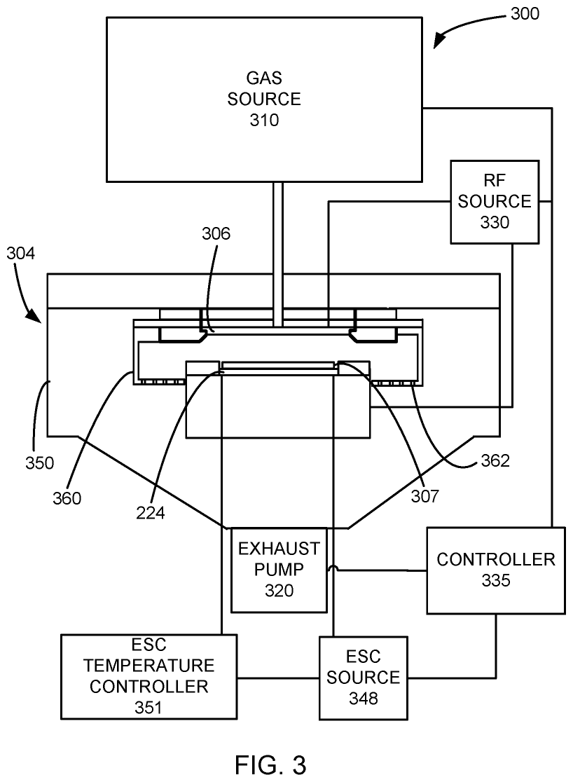

Finally, the ESC 224 is mounted in a semiconductor processing chamber (step 120). FIG. 3 is a schematic view of a semiconductor processing system 300 for plasma processing substrates, where the component may be installed in an embodiment. In some embodiments, the semiconductor processing system 300 comprises a gas distribution plate 306 providing a gas inlet and the ESC 224, within a semiconductor processing chamber 304, enclosed by a chamber wall 350. Within the semiconductor processing chamber 304, a substrate 307 is positioned on top of the ESC 224. The ESC 224 may provide a bias from an ESC power source 348. A gas source 310 is connected to the semiconductor processing chamber 304 through the gas distribution plate 306. An ESC temperature controller 351 is connected to the ESC 224 and provides temperature control of the ESC 224. A radio frequency (RF) power source 330 provides RF power to the ESC 224 and an upper electrode. In this embodiment, the upper electrode is the gas distribution plate 306. In a preferred embodiment, 13.56 megahertz (MHz), 2 MHz, 60 MHz, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the semiconductor processing chamber 304. The high flow liner 360 confines gas from the gas source and has slots 362. The slots 362 maintain a controlled flow of gas to pass from the gas source 310 to the exhaust pump 320. An example of such a semiconductor processing chamber is the Exelan Flex™ etch system manufactured by Lam Research Corporation of Fremont, CA. The process chamber can be a CCP (capacitively coupled plasma) reactor or an ICP (inductively coupled plasma) reactor.

The semiconductor processing chamber 304 is used to process a plurality of wafers (step 124). The semiconductor processing may be one or more processes of etching, depositing, passivating, or another process. The semiconductor processing may be at least one of a plasma process and a non-plasma process. Such processes may expose the ESC 224 to plasmas containing halogen and/or oxygen chemistries. In some embodiments, a plurality of wafers are serially or sequentially processed, where a wafer is placed on the ESC 224 and processed and then removed so that another wafer may be placed on the ESC 224 and processed.

In some embodiments, the ceramic coating 212 deposited by atmospheric plasma spraying has a splat like morphology with a significant amount of porosity. The laser glazing process, which consists of laser heating and subsequent cooling via rapid solidification process, causes the ceramic coating 212 to melt and subsequently solidify, often with crystallization, in a denser and less porous ceramic coating than the precursor coating. In some embodiments, the cooling or quench process results in a coating that is multicrystalline, and where the majority of crystal structures are in the lowest thermodynamic free energy state. In some embodiments, for an aluminum oxide ceramic coating, the atmospheric plasma spraying deposits some gamma crystalline state (phase) aluminum oxide, where the gamma crystalline state has a higher thermodynamic free energy state. The laser glazing of the aluminum oxide coating remelts the coating and allows a longer time for the coating to cool down, allowing most of the aluminum oxide coating to recrystallize to mostly an alpha crystalline state aluminum oxide. The alpha crystalline state is the most stable of the aluminum oxide crystalline states, having the lowest thermodynamic free energy state. Therefore, the laser glazing process removes more of the unstable states of the aluminum oxide coating. For an yttrium oxide coating, atmospheric plasma spraying would deposit some higher thermodynamic free energy state monoclinic crystalline state yttrium oxide, and may also contain amorphous phase material. Laser glazing causes the yttrium oxide to melt and recrystallize so that most of the yttrium oxide is at the lowest thermodynamic free energy state of a cubic crystalline state yttrium oxide.

In some embodiments, the component body 200 is an aluminum based, which includes aluminum alloys, baseplate and the ceramic coating is an atmospheric plasma spray coating of aluminum oxide ceramic. The coating has a thickness in the range of 40 μm to 600 μm. In some embodiments, the aluminum oxide ceramic coating has a thickness between 100 μm to 300 μm. In some embodiments, the aluminum oxide ceramic coating has a thickness between 200 μm to 600 μm. In some embodiments, an atmospheric plasma spray coating of aluminum oxide forms a columnar microstructure. In some embodiments, most of the atmospheric plasma spray coating has a columnar microstructure that is orthogonal to the surface of the component, such as the component body 200. The columnar microstructure is problematic in a semiconductor processing chamber. The columnar microstructure may be problematic if the columnar microstructure has pores that penetrate from the surface of the coating to the substrate. In addition, the columnar microstructure may be mechanically weak and can create vertical fractures with a coefficient of thermal expansion (CTE) mismatch between the coating and the substrate. In some embodiments, the laser glazing rasters 10% to 100% of the thickness of the ceramic coating. In some embodiments, the laser glazing glazes at least 70% of the thickness of the ceramic coating. In some embodiments, the laser glazing glazes 70% to 80% of the thickness of the ceramic coating. In some embodiments, the laser glazing glazes in the range of 70 μm to 350 μm deep into the ceramic coating. In some embodiments, the laser glazing changes the atmospheric plasma spray coating from having a columnar microstructure to a non-columnar microstructure. In some embodiments, the laser glazed portion of the aluminum oxide coating has a dendritic microstructure across the thickness of the laser glazed portion of the aluminum oxide coating. In some embodiments, the laser glazed portion of the aluminum oxide coating has more of a dendritic microstructure than a columnar microstructure. In some embodiments, the laser glazing of the aluminum oxide ceramic coating transforms gamma phase aluminum oxide formed by the atmospheric plasma spray deposition to alpha phase aluminum oxide. In some embodiments, the laser glazed aluminum oxide coating is at least 95% by mass alpha phase aluminum oxide measured by XRD (X-ray diffractometry). In some embodiments, the laser glazed aluminum oxide coating one of is at least 90% or 80% by mass alpha phase aluminum oxide measured by XRD (X-ray diffractometry). In some embodiments, laser glazing coatings with retransformed alpha phase aluminum oxide has a nanohardness in the range of 24-30 gigapascals (GPa). In some embodiments, atmospheric plasma spray coatings with gamma phase aluminum oxide has a nanohardness in the range of 6-10 GPa. In some embodiments, the laser glazing increases the nanohardness from less than 15 GPa to the range of 20 GPa to 40 GPa. The ability to provide an almost complete phase change without damaging the component body is unique. In some embodiments, the coating before the laser glazing has a porosity of greater than 10%. In some embodiments, the coating before the laser glazing has a porosity of greater than 5%. In some embodiments, the coating before the laser glazing has a porosity of greater than 1%. In some embodiments, the laser glazing reduces porosity to provide a laser glazed coating with a porosity of less than 0.5%. In some embodiments, the laser glazing reduces porosity to provide a laser glazed coating with a porosity of less than 0.3%. In some embodiments, the laser glazing reduces porosity to provide a laser glazed coating with a porosity of less than 0.1%. In some embodiments, the aluminum oxide coating is on the surface of the component body, so that there is no anodized coating between the aluminum oxide coating and the component body.

In some embodiments, the laser glazed layer provides at least one of plasma erosion protection, corrosion protection, environmental protection, and voltage breakdown protection. In some embodiments, the laser glazing increases the hardness from less than 900 Vickers hardness number (VHN) to greater than 2000 VHN. In some embodiments, the laser glazing increases the hardness to the range of 2000 VHN to 3000 VHN. In some embodiments, the laser glazing increases the Young's modulus from less than 170 GPa to the range of 290 GPa to 400 GPa. In some embodiments, the laser glazing reduces the surface roughness from an RA roughness being in the range of 6 μm to 10 μm to a RA roughness in the range of 0.5 μm to 5 μm. In some embodiments, the roughness is in the range of 1 μm to 4.5 μm after cleaning. In some embodiments, the laser glazing reduces the lattice strain from about 0.40% to the range of about 0.10% to 0.30%. In some embodiments, the laser glazed portion has a lattice strain in the range of 0.15% to 0.20%. In some embodiments, the laser glazing increase the fracture toughness from less than 1.85 millipascals per meter square (MPa/m²) to the range of 2.0 MPa/m² to 3.0 MPa/m². Laser glazing decreases non-indentation from greater than 500 nm depth of penetration at a load of 30,000 micronewtons (un) to a depth of penetration in the range of 100 nm to 300 nm at a load of 30,000 μn.

In some embodiments, where the atmospheric plasma spray coatings are 200 μm thick, laser glazing using a continuous CO₂ laser with a power in the range of 600 W to 700 W that is scanned at a range of 10 mm/sec provided a reduced coefficient of friction and increased corrosion resistance.

In some embodiments, the component body is an aluminum baseplate. In some embodiments, the surface of the aluminum baseplate is anodized to form an anodized layer. In some embodiments, the anodized layer has a thickness in the range of 10 μm to 100 μm. In some embodiments, the anodized layer has a thickness in the range of 30 μm to 80 μm. In some embodiments, the ceramic coating is an atmospheric plasma spray coating of at least one of yttria and a mixed metal oxide. Mixed metal oxides are oxides with at least two different metals in the form of AₓB_{y}O_{z}, where x, y, and z are integers and A and B are different metals such as at least one of magnesium, yttrium, hafnium, zirconium, lanthanum, samarium, erbium, cerium, gadolinium, ytterbium, and another lanthanide. Mixed metal oxides include yttrium aluminum oxide and magnesium aluminum oxide. Mixed metal oxides also include pyrochlores. A pyrochlore is a mineral with a general formula of A₂B₂O₇ or A₂B₂O₆, where A and B are 3+ and 4+ metal cations, respectively. In some embodiments, the coating has a thickness in the range of 40 μm to 600 μm. In some embodiments, an atmospheric plasma spray coating of the mixed metal oxide forms a columnar microstructure. In some embodiments, the laser glazing glazes at least 70% of the thickness of the ceramic coating. In some embodiments, the laser glazing glazes 70% to 80% of the thickness of the ceramic coating. In some embodiments, the laser glazing glazes in the range of 70 μm to 350 μm deep into the ceramic coating. In some embodiments, the laser glazing changes the atmospheric plasma spray coating from having a columnar microstructure to a non-columnar microstructure. In some embodiments, the laser glazing increases the density of the coating. In some embodiments, the laser glazing reduces porosity to provide a laser glazed coating with a porosity of less than 0.5%. In some embodiments, the laser glazing reduces porosity to provide a laser glazed coating with a porosity of less than 0.3%. In some embodiments, the laser glazing reduces porosity to provide a laser glazed coating with a porosity of less than 0.1%. In some embodiments, the atmospheric plasma spray coating has a lamellar microstructure that is parallel to the surface of the component body.

In other embodiments, other components of semiconductor processing systems with metal bodies that are exposed to plasma may be provided. Plasma facing surfaces of the components may have a plasma spray ceramic coating. The surface of the ceramic coating may be a laser glazed ceramic coating.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, the component comprising:
a metal component body; and
a ceramic coating on a surface of the metal component body, wherein the ceramic coating has a thickness in a range of 40 μm to 600 μm, and wherein a surface of the ceramic coating is a laser glazed ceramic coating.

2. The component, as recited in claim 1, wherein at least 70% of the thickness of the ceramic coating is a laser glazed ceramic coating.

3. The component, as recited in claim 1, further comprising an anodized layer between the metal component body and the ceramic coating.

4. The component, as recited in claim 1, wherein the laser glazed ceramic coating has a thickness in a range of 70 μm to 350 μm.

5. The component, as recited in claim 1, wherein the ceramic coating comprises at least one of yttria, aluminum oxide, magnesium aluminum oxide, and yttrium aluminum oxide.

6. The component, as recited in claim 1, wherein the ceramic coating comprises aluminum oxide, and wherein the laser glazed ceramic coating has a dendritic microstructure.

7. The component, as recited in claim 1, wherein the ceramic coating comprises aluminum oxide, and wherein the laser glazed ceramic coating comprises alpha phase aluminum oxide.

8. The component, as recited in claim 1, wherein the laser glazed ceramic coating has a porosity of less than 0.5%.

9. The component, as recited in claim 1, wherein the laser glazed ceramic coating has a hardness greater than 2000 VHN.

10. The component, as recited in claim 1, wherein the component is part of an electrostatic chuck.

11. A method for forming a component for use in a semiconductor processing chamber, comprising:
providing a metal component body;
plasma spraying a ceramic coating over a surface of the metal component body; and
laser glazing a surface of the ceramic coating.

12. The method, as recited in claim 11, further comprising anodizing a surface of the metal component body before plasma spraying the ceramic coating over the surface of the metal component body.

13. The method, as recited in claim 11, further comprising mounting the component in a semiconductor processing chamber.

14. The method, as recited in claim 13, further comprising using the semiconductor processing chamber for serially processing a plurality of wafers while the component is mounted in the semiconductor processing chamber, wherein the serially processing of the plurality of wafers exposes the component to a plasma.

15. The method, as recited in claim 13, wherein the component is used as an electrostatic chuck.

16. The method, as recited in claim 11, wherein the ceramic coating has a thickness in a range of 40 μm to 600 μm.

17. The method, as recited in claim 16, wherein the laser glazing causes at least 70% of the thickness of the ceramic coating to become a laser glazed ceramic coating.

18. The method, as recited in claim 11, wherein the laser glazing forms laser glazed ceramic coating that has a thickness in a range of 70 μm to 350 μm.
